(19) United States
(12) Patent Application Publication
(10) Pub. No.: US 2006/0067375 A1
(43) Pub. Date: Mar. 30, 2006

(54) Semiconductor laser array and semiconductor laser device having semiconductor laser array

(75) Inventors: Masanori Yamada, Kanagawa-ken (JP); Koichi Matsushita, Kanagawa-ken (JP); Hironobu Miyasaka, Kanagawa-ken (JP); Kazuya Tsunoda, Kanagawa-ken (JP)

Correspondence Address: BANNER & WITCOFF, 1001 G STREET N W, SUITE 1100, WASHINGTON, DC, 20001, US

(73) Assignee: Kabushiki Kaisha Toshiba, Tokyo (JP)

(21) Appl. No.: 11/232,464

(22) Filed: Sep. 22, 2005

(30) Foreign Application Priority Data
Sep. 24, 2004 (JP) 2004-278289

(51) Int. Cl. H01S 5/00

(52) U.S. Cl. 372/50.12

(57) ABSTRACT

One aspect of the present invention may include a semiconductor laser array, comprising: a substrate; a first laser element on the substrate, the first laser element having a first resonator; a second laser element on the substrate, the second laser element having a second resonator, the second resonator being shorter in cavity length than the first resonator; and a protrusion on the substrate, the protrusion being substantially equal in height from the substrate with one of the first laser element and the second laser element.

### CROSS REFERENCES TO RELATED APPLICATION

This application is based upon and claims the benefit of priority from the prior Japanese Patent Application No. 2004-278289, filed on Sep. 24, 2004; the entire contents of which are incorporated herein by reference.

### BACKGROUND OF THE INVENTION

A conventional DVD (digital versatile disc) recorder is equipped to play and record CDs. The conventional DVD recorder has a 650 nm high power red laser for playing and recording DVDs and a 780 nm low power infrared laser for playing CDs.

Recently, a monolithic laser element that emits usable light is shown in Japanese patent laid open No. 2004-87564. However, the suitable cavity length of resonator is different between a 650 nm laser and a 780 nm laser.

A semiconductor laser having two different cavity lengths of resonators is shown in the Japanese patent laid open No. H4-245494.

When this semiconductor laser is mounted on a submount with a junction down, the stress on the long resonator and the stress on the short resonator are not even.

This is because the contact area to the submount for the two different length resonators is different. The stress is concentrated to a laser having the short resonator. This may adversely affect the characteristics of one of the lasers.

### SUMMARY

Aspects of the present invention address one or more of the issues associated with conventional laser arrays.

### BRIEF DESCRIPTION OF THE DRAWINGS

FIG. 1 is an overview of a semiconductor laser array in accordance with a first embodiment of the present invention.

FIG. 2A is a plane view of a semiconductor laser array in accordance with a first embodiment and FIG. 2B is a cross-sectional view of A-A line in FIG. 2A.

FIGS. 3A-3D are a cross-sectional view of a part of the manufacturing process of the semiconductor laser array of the first embodiment in accordance with aspects of the present invention.

FIGS. 4A-4D are a cross-sectional view of a part of the manufacturing process of the semiconductor laser array of the first embodiment in accordance with aspects of the present invention.

FIGS. 5A-5C are a cross-sectional view of a part of the manufacturing process of the semiconductor laser array of the first embodiment in accordance with aspects of the present invention.

FIG. 6A is an overview of a semiconductor laser device of the first embodiment and FIG. 6B is an overview of a semiconductor laser array mounted on a sub mount in accordance with aspects of the present invention.

FIG. 7A is an overview and FIG. 7B is a plane view of a semiconductor laser array consistent with a second embodiment of the present invention.

FIG. 8A is an overview and FIG. 8B is a plane view of a semiconductor laser array consistent with a second embodiment in accordance with aspects of the present invention.

FIG. 9A is an overview and FIG. 9B is a plane view of a semiconductor laser array consistent with a second embodiment in accordance with aspects of the present invention.

FIG. 10A is an overview of a semiconductor laser device of a third embodiment and FIG. 10B is an overview of a semiconductor laser array mounted on a sub mount of the third embodiment in accordance with aspects of the present invention.

FIG. 11A and 11B are schematic views showing operations of a semiconductor laser device of a third embodiment in accordance with aspects of the present invention.

### DETAILED DESCRIPTION

Embodiments of the present invention will be explained with reference to the drawings.

It is noted that various connections are set forth between elements in the following description. It is noted that these connections in general and, unless specified otherwise, may be direct or indirect and that this specification is not intended to be limiting in this respect.

In at least one aspect of the present invention, a semiconductor laser array may include a substrate; a first laser element on the substrate, the first laser element having a first resonator; a second laser element on the substrate, the second laser element having a second resonator, the second resonator being shorter in cavity length than the first resonator; and a protrusion on the substrate, the protrusion being substantially equal in height from the substrate with one of the first laser element and the second laser element.

Another aspect of the present invention may include semiconductor laser array having a substrate, a first laser element on the substrate, the first laser element having a first resonator, a second laser element on the substrate, the second laser element having a second resonator, the second resonator being shorter in cavity length than the first resonator, and a supporting member on the substrate, the supporting member being separated from the first laser element by a first trench and the supporting member being separated from the second laser element by a second trench.

A further aspect of the present invention may include a semiconductor laser device having a submount; a semiconductor laser array mounted on the submount, the semiconductor laser array having; a substrate, a first laser element on the substrate having a first resonator, the first laser element provided between the submount and the substrate, and a second laser element on the substrate having a second resonator, the second resonator being shorter in cavity length than the first resonator, the second laser element provided between the submount and the substrate; a supporting member provided between the submount and the substrate of the semiconductor laser array.

### The First Embodiment

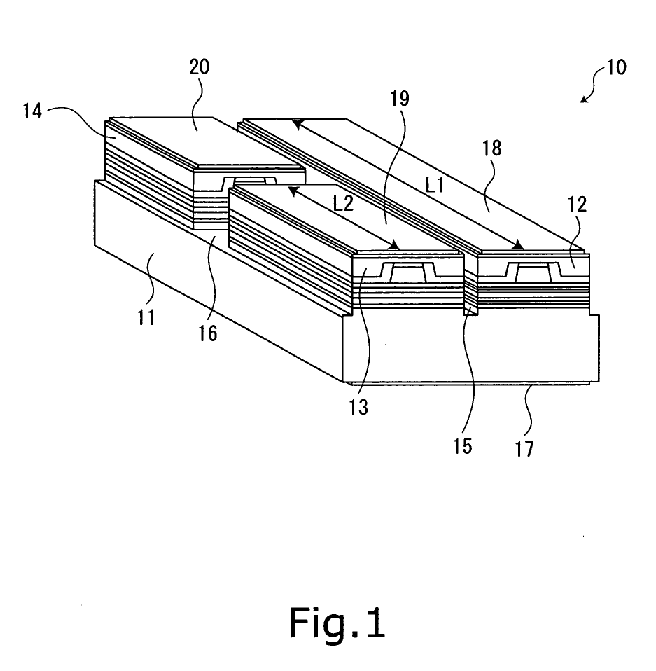

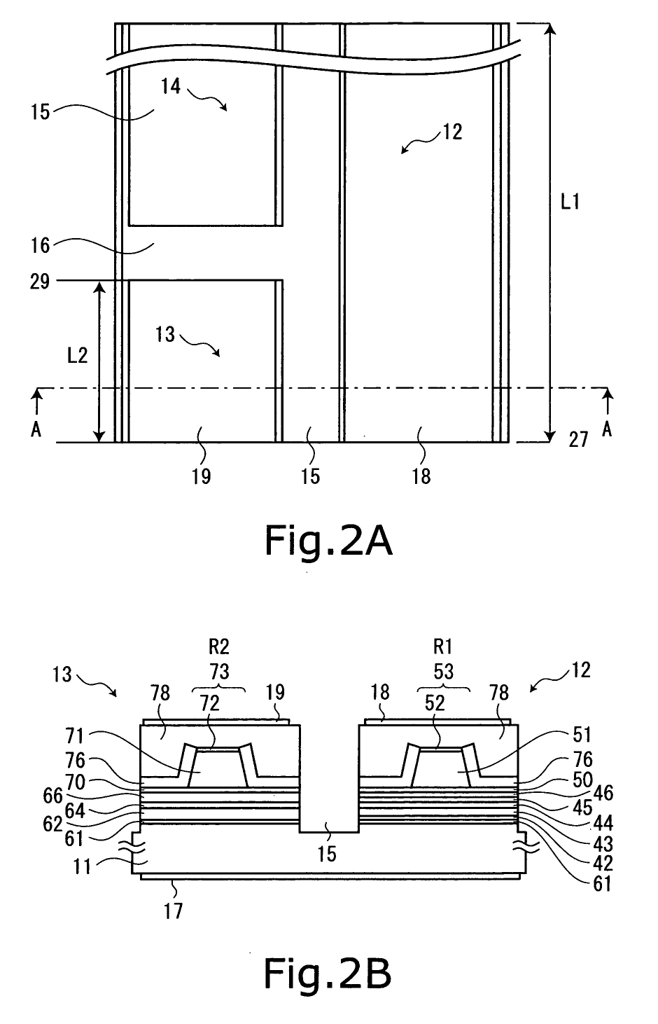

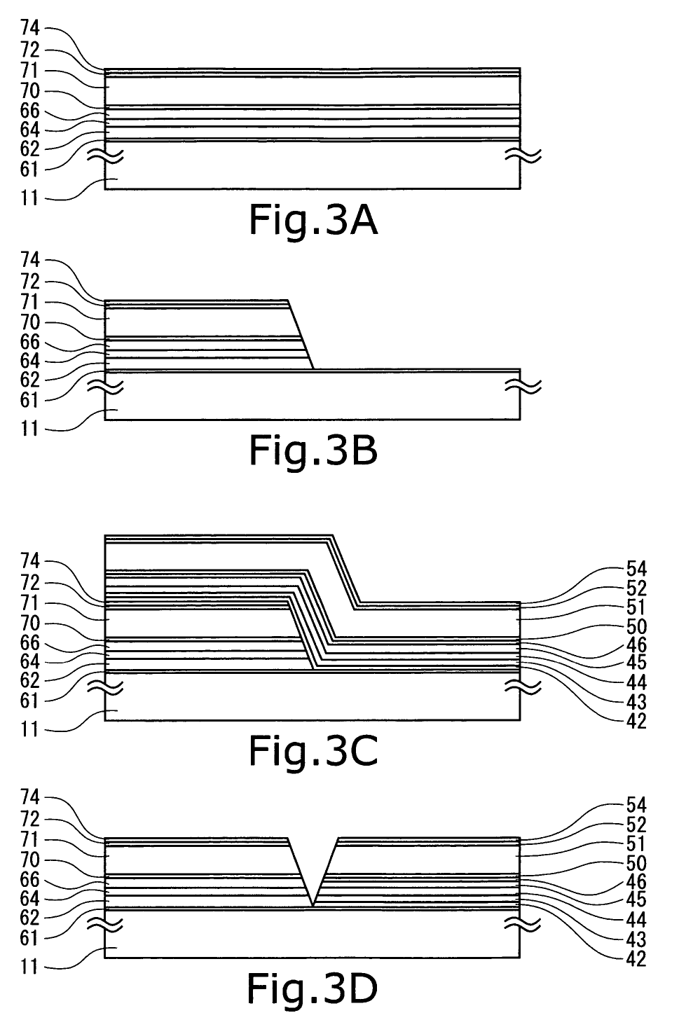

A first embodiment of the present invention will be explained hereinafter with reference to FIG. 1 to FIG. 6B. FIG. 1 is an overview of a semiconductor laser array in accordance with a first embodiment of the present invention. FIG. 2A is a plane view of a semiconductor laser array in accordance with a first embodiment and FIG. 2B is a cross-sectional view of A-A line in FIG. 2A. FIGS. 3A-5C are a cross-sectional view of a part of the manufacturing process of the semiconductor laser array of the first embodiment.

As shown in FIG. 1, a semiconductor laser array 10 may include a visible laser element 12, an infrared laser element 13 and a protrusion 14. The visible laser element 12, the infrared laser element 13 and the protrusion 14 are formed on a main surface of an n-type GaAs substrate 11. The visible laser element 12 emits a 650 nm laser. The infrared laser element 13 emits a 780 nm laser. The protrusion 14 has substantially the same layer structure except for electrode with the infrared laser element 13, but the protrusion 14 is not used as a laser element.

Protrusion 14 may also be described as a structure separated from the laser elements 12 and 13.

The visible laser element 12 and the infrared laser element 13 are provided in the vicinity of each other so that an optical axis of the visible laser element 12 and the infrared laser element 13 are substantially parallel. The visible laser element 12 and the infrared laser element 13 are separated by a trench 15. The trench 15 may be provided on the substrate 11.

The protrusion 14 may be separated to visible laser element 12 by the trench 15 and to the infrared laser element 13 by a trench 16.

A cavity length L1 of resonator of the visible laser element 12 may be designed so that the visible laser element 12 may be able to emit a high power laser. A cavity length L2 of resonator of the infrared laser element 13 may be designed so that a threshold current (Ith) of the infrared laser element 13 may be reduced.

The cavity length L1 is longer than the cavity length L2. The cavity lengths L1 and L2 may alternatively be described as lengths along the laser resonators' axes (optical axes). Further, these lengths may be alternatively described as in the direction of the light output from each laser.

An n-side electrode 17 may be provided on the back surface of the substrate 11.

A p-side electrode 18 and a p-side electrode 19 are provided on the top surface of the visible laser element 12 and infrared laser element 13, respectively. The n-side electrode 17 and the p-side electrodes 18, 19 are provided for injecting current into an active layer of the visible laser element 12 and infrared laser element 13.

An insulating layer 20 may be provided on the top surface of the protrusion 14.

The insulating layer 20 is used to prevent injecting of current into active layer of the protrusion 14. Accordingly, the protrusion 14 may have substantially the same multilayer structure, except for the insulating layer 20 as the infrared laser element 13. The protrusion 14 is not used for emitting a laser. This is because the protrusion 14 does not have a p-side electrode. Instead of the p-side electrode, the protrusion 14 has the insulating layer 20. In other words, the protrusion is dummy laser element. One example for the insulating layer is SiO2. Alternatively, the protrusion may have less layers and not include all layers that would make it a laser element but for the lack of the p-side electrode.

The height of the protrusion 14 from the substrate 11 may be substantially equal to the height of the visible laser element 12 and infrared laser element 13.

The top surface of the protrusion 14, the top surface of the visible laser element 12, and the top surface of the infrared laser 13 may be substantially in the same plane.

The detail structure of semiconductor laser array 10 of this embodiment is explained with reference to FIGS. 2A and 2B hereinafter.

As shown in FIG. 2A, the visible laser element 12, the infrared laser element 13 and the protrusion 14 are rectangular shape in the plane view. One side (right side in FIG. 2A) of the protrusion 14 is parallel to a side face (left side in FIG. 2A) of resonator of the visible laser element 12. One side (down-side in FIG. 2A) of the protrusion 14 is parallel to a side face (upper side in FIG. 2A) of the resonator of the infrared laser element 13.

A multilayer structure of the visible laser element 12 is explained hereinafter. As shown in FIG. 2B, in the visible laser element 12, an n-type GaAs buffer layer 61, an n-type In_{0.5}(Ga_{0.3}Al_{0.7})_{0.5}P cladding layer 42 (abbreviated InGaAlP cladding layer), an n-type In_{0.5}(Ga_{0.4}Al_{0.6})_{0.5}P guide layer 43 (abbreviated InGaAlP guide layer), an active layer 44, a p-type InGaAlP guide layer 45 and a first p-type

InGaAlP cladding layer 46 are formed on the substrate 11 in this order. The active layer 44 may be a MQW (Multi-Quantum Well) of In_{0.5}Ga_{0.5}P/In_{0.5}(Ga_{0.5}Al_{0.5})P_{0.5}.

A p-type In_{0.5}Ga_{0.5}P etching stop layer 50 is provided on the first p-type cladding layer 46. A second p-type InGaAlP cladding layer 51 and a p-type cap layer 52 are formed as a ridge stripe waveguide structure 53 on the etching stop layer 50.

A n-type InAlP current block layer 76 is provided on the p-type In_{0.5Ga}_{0.5}P etching stop layer 50, a side of the second p-type InGaAlP cladding layer 51 and a side of the cap layer 52. In other words, the current block layer 76 is provided except for ridge stripe waveguide structure 53.

A p-type contact layer 78 is provided on the current block layer 76 and the cap layer 52. A top surface of the contact layer 78 is flat. A p-side electrode 18 is provided on the contact layer 78.

A structure of the infrared laser element 13 is explained hereinafter.

As shown in FIG. 2B, in the infrared laser element 13, the n-type GaAs buffer layer 61, an n-type InGaAlP cladding layer 62, an Ga_{0.8}Al_{0.2}As (abbreviated GaAlAs) active layer 64, and a first p-type InGaAlP cladding layer 66 are formed on the substrate 11 in this order.

A p-type InGaP etching stop layer 70 is provided on the first p-type cladding layer 66. A second p-type InGaAlP cladding layer 71 and a p-type cap layer 72 are formed as a ridge stripe waveguide structure 73 on the etching stop layer 70.

The n-type InAlP current block layer 76 is provided on the p-type InGaP etching stop layer 70, a side of the second p-type InGaAlP cladding layer 71 and a side of the low resistance 72. In other words, the current block layer 76 may be provided except for the ridge stripe waveguide structure 73.

A p-type contact layer 78 is provided on the current block layer 76 and the cap layer 72. A top surface of the contact layer 78 is flat. A p-side electrode 19 may be provided on the contact layer 78.

The n-side electrode 17 is provided on the back surface of the substrate 11.

As mentioned above, the visible laser element 12 and the infrared laser element 13 (which emits different wavelength laser) are provided on one substrate. The cavity lengths of resonator L1 and L2 are capable of being set independently in order to reduce the threshold current and the power consumption.

The structure of the protrusion 14 is explained hereinafter. The protrusion 14 has the same layer structure except for the insulating layer 20 as the infrared laser element 13. On the substrate 11 the n-type GaAs buffer layer 61, the n-type InGaAlP cladding layer 62, the GaAlAs active layer 64, the first p-type InGaAlP cladding layer 66, the p-type InGaP etching stop layer 70, the second p-type InGaAlP cladding layer 71 and the p-type cap layer 72, the n-type InAlP current block layer 76 and the p-type contact layer 78 are formed.

On the above mentioned layer structure, the insulating layer 20 is provided on the contact layer 78. The insulating layer 20 makes the protrusion not to injected current into and not to use for emitting laser.

A metal such as the same material as the p-side electrodes 18, 19 may be provided between the top surface of the contact layer 78 and the insulating layer 20. This also prevents the current from being injected into protrusion 14.

The manufacturing process of the semiconductor laser array 10 is explained with reference to FIGS. 3A-5C. FIGS. 3A-5 are shown cross-sectional views of respective parts of the manufacturing process of the semiconductor laser array of the first embodiment.

As shown in FIG. 3A, the n-type GaAs buffer layer 61, the n-type InGaAlP cladding layer 62, the Ga_{0.8}Al_{0.2}As (abbreviated GaAlAs) active layer 64, the first p-type InGaAlP cladding layer 66, the p-type InGaP etching stop layer 70, the second p-type InGaAlP cladding layer 71 and the p-type 72 and the n-type GaAs cap layer 74 may be grown on the substrate 11 in this order by MOCVD (Metal Organic Chemical Vapor Deposition) or other techniques.

As shown in FIG. 3B, the cap layer 74—the n-type InGaAlP cladding layer 61 may be partially removed by using photolithography and etchings. The n-type GaAs buffer layer 61 is exposed.

As shown in FIG. 3C, the n-type InGaAlP cladding layer 42, the n-type InGaAlP guide layer 43, the MQW active layer 44, the p-type InGaAlP guide layer 45, the first p-type InGaAlP cladding layer 46, the p-type In_{0.5}Ga_{0.5}P etching stop layer 50, the second p-type InGaAlP cladding layer 51, the p-type cap layer 52 and the p-type cap layer 54 are formed on the buffer layer 61 and the cap layer 74 in this order by MOCVD (Metal Organic Chemical Vapor Deposition) or other techniques.

As shown in FIG. 3D, the layers from the p-type cap layer 54—the n-type InGaAlP cladding layer 42 which are on the cap layer 74, are removed by using photolithography and etchings. The cap layer 74 is exposed.

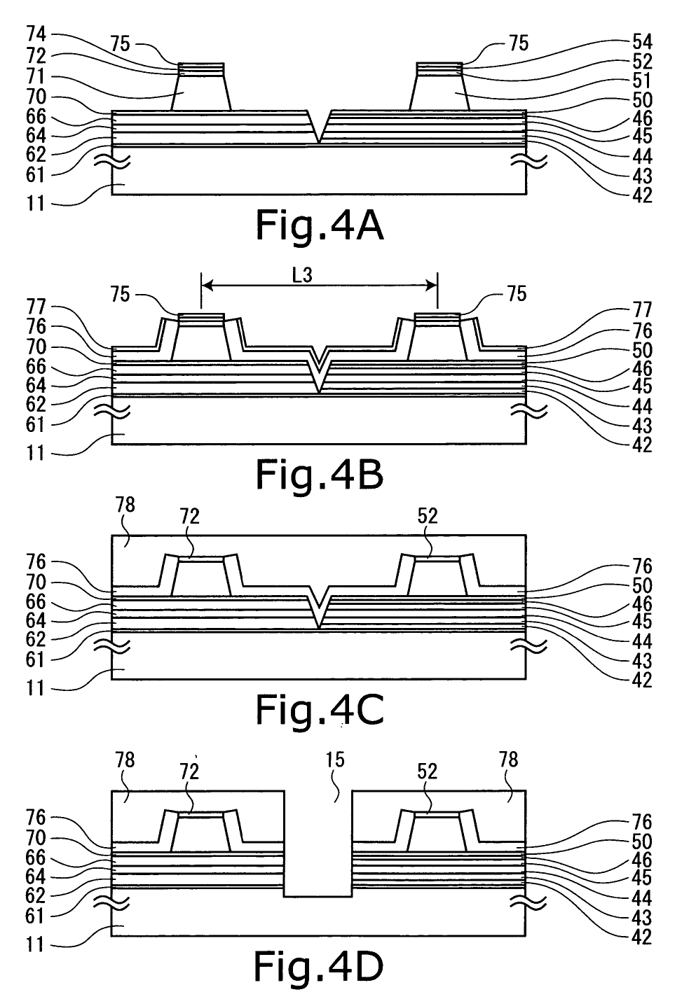

As shown in FIG. 4A, a stripe shaped mask 75 such as SiO2 is formed on the cap layer 74. A distance L3 between masks 75 is a distance between an emitting center of the visible laser element 12 and the infrared laser element 13. One example of L3 is 110 micrometers. The n-type cap layers 54, 74, the p-type cap layers 52, 72 and the p-type cladding layers 51, 71 are removed by wet etching. This etching is stopped at reaching the etching stop layers 50, 70. A stripe shaped second p-type cladding layers 51 and 71 remain.

As shown in FIG. 4B, the n-type InAlP current block layer 76 and an n-type GaAs cap layer 77 are selectively formed by MOCVD. Namely the n-type InAlP current block layer 76 is formed on the etching stop layers 50, 70 and on the side of stripe shaped the second p-type cladding layers 51 and 71. The n-type GaAs cap layer 77 is formed on the n-type InAlP current block layer 76.

As shown in FIG. 4C, the mask 75 and the n-type GaAs cap layers 54, 74, 77 are removed by etching. A p-type GaAs contact layer 78 is grown on the cap layers 52,72. The p-type GaAs contact layer 78 is formed such as MOCVD.

As shown in FIG. 4D, the trench 15 is formed. A bottom of the trench 15 reaches to the substrate 11. The trench 15 is formed by RIE (reactive ion etching). The visible laser element 12 and the infrared laser element 13 are separated and insulated by the trench 15.

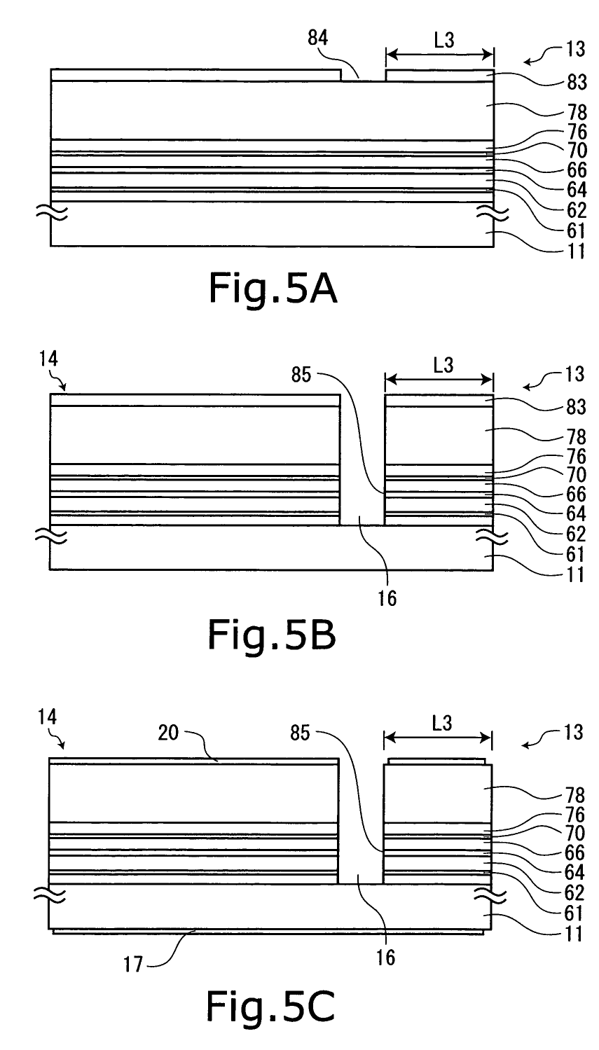

The process for manufacturing the trench 16 (which separates the infrared laser element 13 and the protrusion 14) is explained hereinafter. FIGS. 5A-5C are a cross-sectional views cut along the longitudinal direction of the resonator of the infrared laser element 13.

As shown in FIG. 5A, a photo resist mask 83 is formed on the contact layer 78. The photo resist mask 83 has opening 84. The opening 84 is formed so that the cavity length L2 of the resonator is obtained. In one example, the length along the longitudinal direction (optical axis) of the resonator is about 5 micrometers and the width along the perpendicular direction of the resonator is about 1 micrometer.

As shown in FIG. 5B, the trench 16 which is substantially vertical to the substrate 11 is formed by RIE. The trench 16 is reached to the substrate 11 and the substrate 11 is exposed in the trench 16. Therefore, a rear end face 85 of the infrared laser element 13 is formed and the protrusion 14 is separated from the infrared laser element 13.

As shown in FIG. 5C, the p-side electrode 19 is formed on the GaAs contact layer 78 of the infrared laser element 13 and p-side electrode (not shown in FIG. 5C) is formed on the GaAs contact layer 78 of the visible laser element 12. The insulating layer 20 is formed on the GaAs contact layer 78 of the protrusion 14.

Furthermore the substrate 11 is polished to be thick. The n-side electrode 17 is formed on the back surface of the substrate 11. The p-side electrodes 18, 19 are annealed to be alloy.

Furthermore, the cleavage process is operated. So the semiconductor laser array 10 as shown in FIG. 1 is created.

In this embodiment, the trench 16 is formed after the trench 15 is formed. But the trench 16 may be formed at the same manufacturing step of forming trench 15 or formed before trench 15 is formed.

In case that the distance L3 between the emitting center of the laser between the laser element 12 and 13 is 110 micrometers, the cavity length of resonator L1, L2 may be 1500 micrometers and the light output of the laser element 13 may be 7 mW, the power consumption of laser element 12 and 13 is 140 mW, respectively. In a single infrared laser element, in case that the cavity length of the laser element is 400 micrometers and the light output of the laser element is 7 mW, the power consumption of laser element is 70 mW. Namely the shorter cavity length of resonator is preferable for reducing the power consumption.

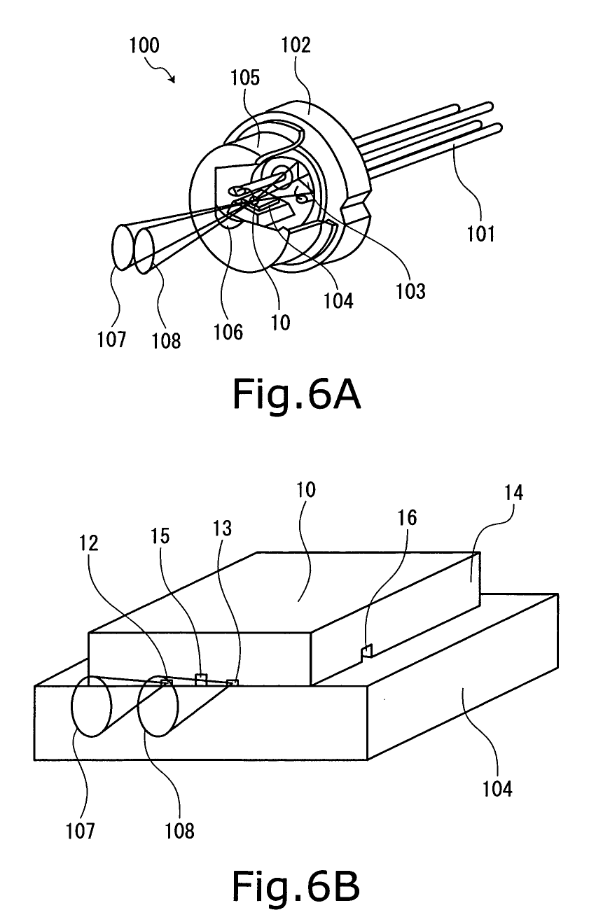

FIG. 6A is an overview of a semiconductor laser device of the first embodiment and FIG. 6B is an overview of a semiconductor laser array mounted on a submount.

As shown in FIG. 6A, a multiple wavelength laser device 100 of this embodiment has the semiconductor laser array 10, four leads 101, a stem 102, a photodiode 103, a submount 104, a metal cap 105 and a window 106.

The semiconductor laser array 10 may eventually be mounted on submount 104. The submount 104 is fixed to the stem 102. The four leads 101 are extended from the stem 102 to the opposite direction of the main emitting direction of the semiconductor laser array 10.

The photodiode (PD) 103 that is for monitoring laser from the semiconductor laser array 10 are mounted on the stem 102. The monitoring laser received by the PD 103 is used for controlling the semiconductor laser array 10.

The metal cap 105 is enclosure of semiconductor laser array 10 and PD 103 and fixed to the stem 102.

The window 106 is provided on the metal cap 105 and a visible laser 107 and an infrared laser 108 are emitted from the window 106 toward outside of the multiple wavelength laser device 100.

As shown in FIG. 6B, the semiconductor laser array 10 is mounted on the submount 104 by junction down (up-side down). In other words, the p-side electrodes 18 and 19 face the submount 104 and the n-side electrodes 17 face up-side. The p-side electrodes 18 and 19 and the submount 104 are adhered by Au—Sn eutectic solder.

In this case, the protrusion 14 is contact with the submount 104 without an adhesive. So the top face of the semiconductor laser array 10, that is p-side electrodes 18, 19 and insulating layer 20,

In this embodiment, the protrusion is provided on the substrate. The protrusion supports the submount. The protrusion disperses the stress on the semiconductor laser array to the visible laser element, the infrared laser element and itself more evenly.

In case the height of the protrusion is equal to that of the visible laser element or the infrared laser element, the stress is reduced more. It is preferable that the top face of the protrusion, the visible laser element and the infrared laser element is substantially flat.

In this embodiment, it is available that the cavity length of the resonator of the visible laser element and the infrared laser element is set independently. The threshold current of the infrared laser is reduced.

An interposer such as insulating material or a metal may be provided between the protrusion 14 and the submount 104. It is preferable that the thickness of the interposer is substantially equal to that of the solder. This make the contact area between the semiconductor laser array 10 and the submount 104 increased. So the stress on the semiconductor laser array 10 is dispersed more. That is the stress distribution is increased.

### The Second Embodiment

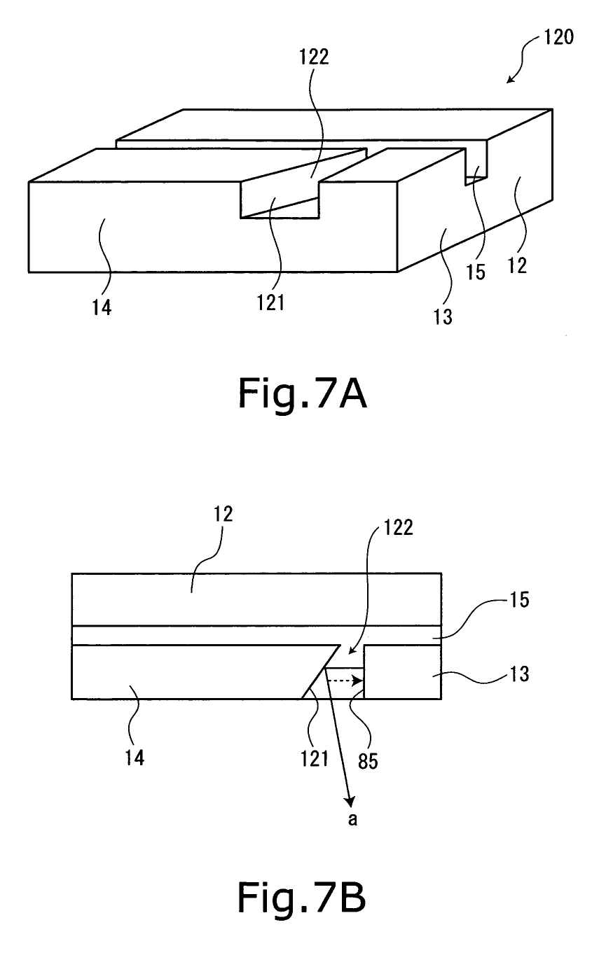

FIGS. 7A-9B are an overview and a plane view of a semiconductor laser array in accordance with a second embodiment of the present invention. With respect to each portion of this second embodiment, the same portions of the semiconductor laser array of the first embodiment shown in FIG. 1 to FIG. 6B are designated by the same reference numerals, and its explanation of such portions is omitted.

In this second embodiment, a part of the protrusion 14 is slanted against the rear end face 85 of the infrared laser element 13.

As shown in FIG. 7A and FIG. 7B, the protrusion 14 of a semiconductor laser array 120 is separated to the infrared laser element 13 by a trench 122. The protrusion 14 has a slanted face 121 that faces the rear end face 85. The slanted face 121 is toward outside of the semiconductor laser array 120 and is vertical with the substrate 11.

The laser “a” as illustrated in FIG. 7B emitted from the rear end face 85 is reflected by the slanted face 121 and the reflected laser is toward outside. So the reflected laser entering into the rear end face of the infrared laser element 13 is reduced. Optical feed back of the infrared laser element 13 is reduced. Moreover mode hopping of the longitudinal mode is reduced. So the output of the infrared laser element 13 is stable.

It is preferable that an angle between the slanted face 121 and the rear end face 85 is 0-45 degree. But the angle is not limited to this range. The angle is set so as to reduce the optical feed back.

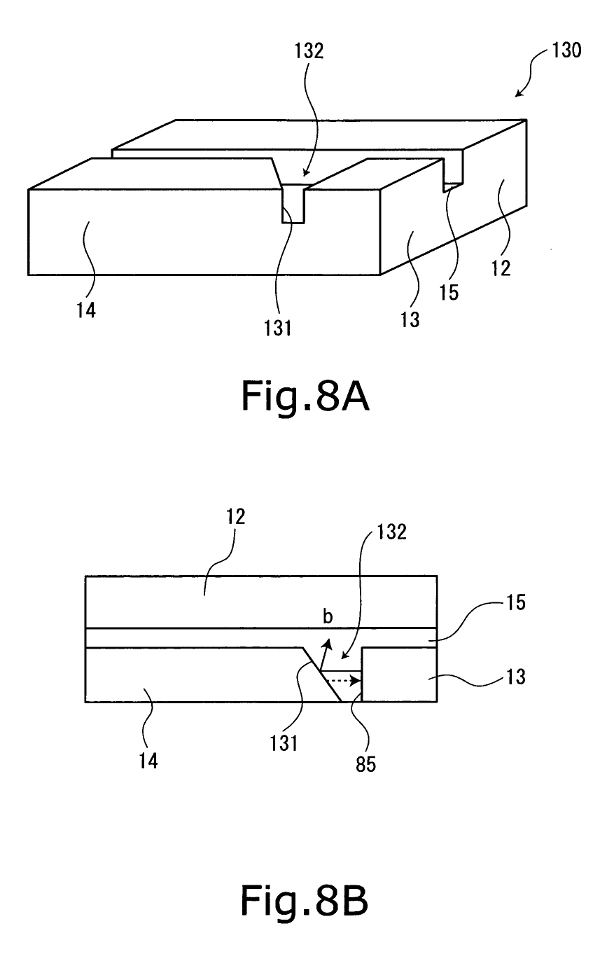

For example, a slanted face of the protrusion may be toward in-side as shown in FIG. 8A and FIG. 8B. The protrusion 14 of a semiconductor laser array 130 is separated to the infrared laser element 13 by a trench 132. The protrusion 14 has a slanted face 131 that faces the rear end face 85 and the side of the visible laser element 12. The slanted face 131 is vertical with the substrate 11.

The laser “b” as illustrated in FIG. 8B emitted from the rear end face 85 is reflected by the slanted face 131 and the reflected laser is toward in-side. So this also makes it lesser the reflected laser entering into the rear end face of the infrared laser element 13.

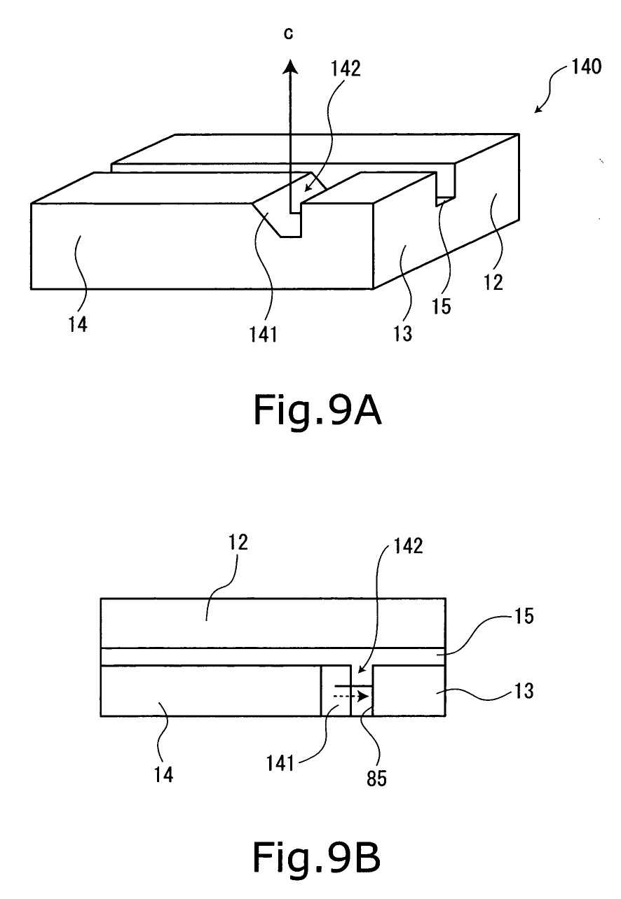

Furthermore, a slanted face of the protrusion may be toward up-side as shown in FIG. 9A and FIG. 9B. The protrusion 14 of a semiconductor laser array 140 is separated to the infrared laser element 13 by a trench 142. The protrusion 14 has a slanted face 141 that faces the rear end face 85 and up-side.

The laser “c” as illustrated in FIG. 9A emitted from the rear end face 85 is reflected by the slanted face 131 and the reflected laser is toward up-side. So the reflected laser entering into the rear end face 85 of the infrared laser element 13 is reduced.

The slanted face 121 and 131 are formed by forming the photo resist mask 83 slanted in the manufacturing process as shown in FIG. 5A. The slanted face 141 may be formed by mesa etching.

### The Third Embodiment

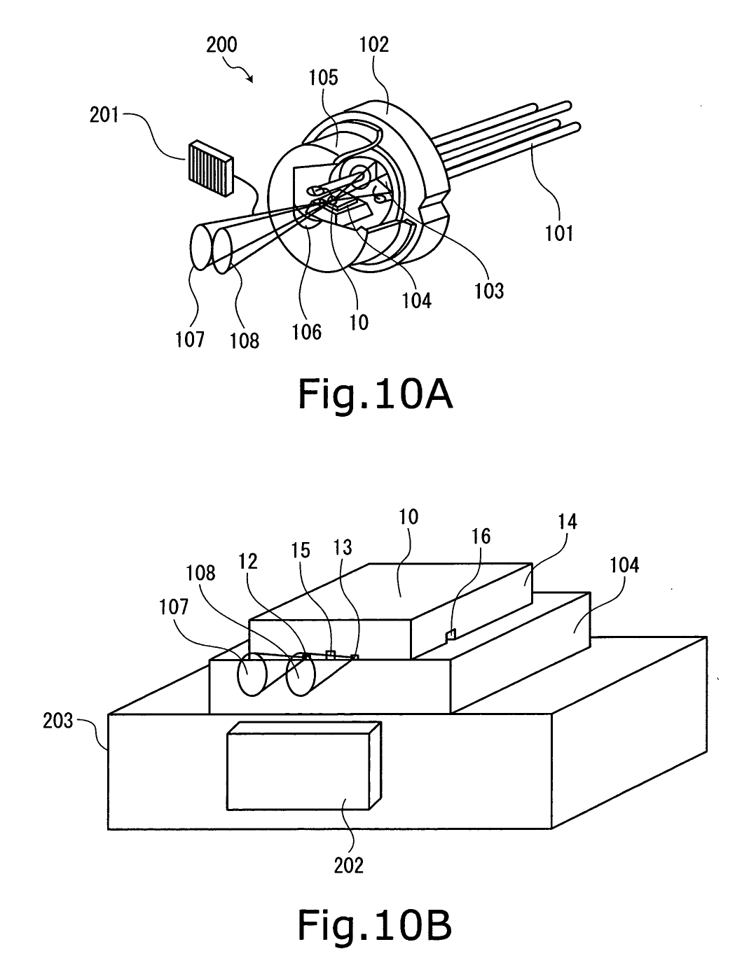

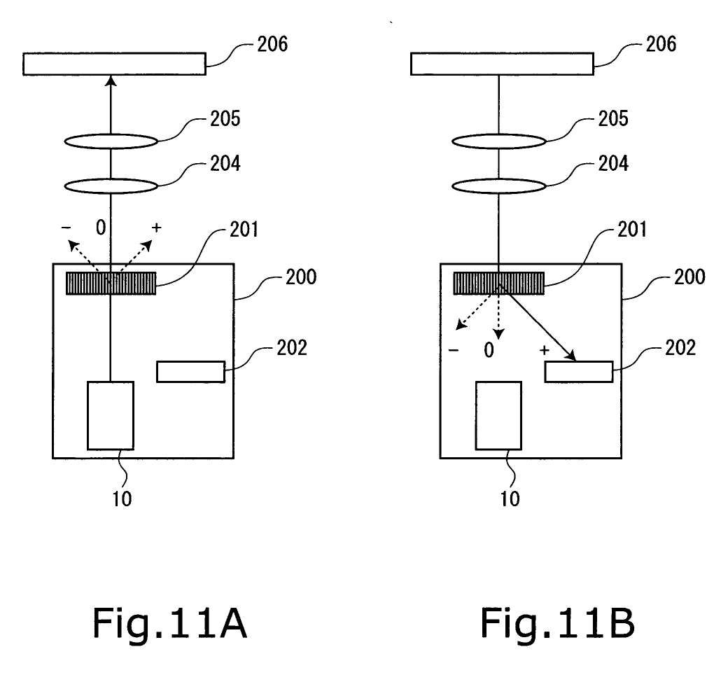

FIGS. 10A-11B are an overview and a plane view of a semiconductor laser array in accordance with a third embodiment of the present invention. With respect to each portion of this third embodiment, the same portions of the semiconductor laser array of the first or second embodiment shown in FIG. 1 to FIG. 9B are designated by the same reference numerals, and its explanation of such portions is omitted.

In this third embodiment, a semiconductor laser device 200 has a diffraction grating (hologram) 201. The diffraction grating 201 is a hologram.

As shown in FIG. 10A, the diffraction grating 201 is provided on an optical axis of the laser. The diffraction grating 201 is in front of the window 106.

As shown in FIG. 10B, the semiconductor laser device 200 have a photo detector 202. The submount 104 is mounted on a base 203. The photo detector 202 is provided on a side of the base 203 with facing the same direction to the emitting direction of laser.

An operation of the semiconductor laser device of this embodiment is explained hereinafter.

As shown in FIG. 11A, laser beam 107, 108 emitted from the semiconductor laser array 10 transmits through the diffraction grating 201 and goes forward. The laser beam 107, 108 is become parallel beam by a lens 204 and is collected by a lens 205.

As shown in FIG. 11B, the laser beam 107, 108 is reflected by a recording medium 206. The reflected laser beam 107, 108 that has recording data return through the same optical path. The reflected laser beam 107, 108 is diffracted by the diffraction grating 201 and reaches the photo detector 202. The reflected laser beam 107, 108 is converted to electronic signal.

The visible laser element 12 is operated for reading data recorded in DVD medium. The infrared laser element 13 is operated for reading data recorded in CD medium.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

The way semiconductor laser array mounted on the submount is not limited to junction down. The semiconductor laser array may be mounted on the submount with junction up (upside up).

Semiconductor laser elements are not limited to GaAlAs, InGaAlP, and GaN lasers. Other semiconductor laser elements are available such as by using a Ill-V compound semiconductor, II-VI compound semiconductor, and so on.

Other embodiment of the present invention may be possible by changing the shape, size, material, and positional relations in design by one skilled in the art.

What is claimed is

1. A semiconductor laser array, comprising:
a substrate;
a first laser element on the substrate, the first laser element having a first resonator;
a second laser element on the substrate, the second laser element having a second resonator, the second resonator being shorter in cavity length than the first resonator; and
a protrusion on the substrate, the protrusion being substantially equal in height from the substrate with one of the first laser element and the second laser element.

2. A semiconductor laser array of claim 1, wherein the first resonator is substantially parallel with the second resonator.

3. A semiconductor laser array of claim 2, wherein the protrusion is provided between a rear end face of the second laser element and a side face of the first laser element.

4. A semiconductor laser array of claim 3, wherein the protrusion has a slanted face against the rear end face of the second laser element.

5. A semiconductor laser array of claim 1, wherein the first laser element is configured to emit longer wavelength laser than the second laser element.

6. A semiconductor laser array, comprising:
a substrate;
a first laser element on the substrate, the first laser element having a first resonator;
a second laser element on the substrate, the second laser element having a second resonator, the second resonator being shorter in cavity length than the first resonator; and
a supporting member on the substrate, the supporting member being separated from the first laser element by a first trench and the supporting member being separated from the second laser element by a second trench.

7. A semiconductor laser array of claim 6, wherein the first resonator is substantially parallel with the second resonator.

8. A semiconductor laser array of claim 7, wherein the protrusion is provided between a rear end face of the second laser element and a side face of the first laser element.

9. A semiconductor laser array of claim 8, wherein the protrusion has a slanted face against the rear end face of the second laser element.

10. A semiconductor laser array of claim 6, wherein the first laser element is configured to emit longer wavelength laser than the second laser element.

11. A semiconductor laser device, comprising:
a submount;
a semiconductor laser array mounted on the submount, the semiconductor laser array having;
a substrate,
a first laser element on the substrate having a first resonator, the first laser element provided between the submount and the substrate, and
a second laser element on the substrate having a second resonator, the second resonator being shorter in longitude than the first resonator, the second laser element provided between the submount and the substrate;
a supporting member provided between the submount and the substrate of the semiconductor laser array.

12. A semiconductor laser device of claim 11 wherein the supporting member has an insulating layer.

13. A semiconductor laser device of claim 11 wherein the supporting member and one of the first laser element and the second laser element have substantially same layers.

14. A semiconductor laser device of claim 11 wherein a part of the supporting member is grown from the substrate.

15. A semiconductor laser device of claim 14 wherein the supporting member has an insulating layer.

16. A semiconductor laser device of claim 14 wherein the first resonator and the second resonator are substantially parallel.

17. A semiconductor laser device of claim 11 wherein the first resonator is substantially parallel with the second resonator.

18. A semiconductor laser device of claim 17, wherein the protrusion is provided between a rear end face of the second laser element and a side face of the first laser element.

19. A semiconductor laser device of claim 18, wherein the protrusion has a slanted face against the rear end face of the second laser element.

20. A semiconductor laser device of claim 11, wherein the supporting member is separated from the first laser element by a first trench and from the second laser element by a second trench.
